(19) United States
(12) Patent Application Publication
(10) Pub. No.: US 2024/0298440 A1
(43) Pub. Date: Sep. 5, 2024

(54) MEMORY DEVICE AND METHOD OF MANUFACTURING THE SAME

(71) Applicant: Winbond Electronics Corp., Taichung City (TW)

(72) Inventors: Wen-Chieh TSAI, Taichung City (TW); Cheng-Ta YANG, Taoyuan City (TW)

(21) Appl. No.: 18/410,202

(22) Filed: Jan. 11, 2024

(30) Foreign Application Priority Data
Mar. 3, 2023 (TW) 112107811

(51) Int. Cl. H10B 41/30; H01L 21/28; H01L 29/423; H01L 29/66; H01L 29/788; H10B 41/10

(52) U.S. Cl. CPC H10B 41/30; H01L 29/40114; H01L 29/42328; H01L 29/66825; H01L 29/7883; H10B 41/10

(57) ABSTRACT

A memory device includes a substrate and a plurality of word lines. The word lines are disposed on the substrate. The word lines extend in the first direction and are arranged in the second direction. The first direction intersects the second direction. The memory device further includes a first sub-select gate extending in the first direction and separated from the outermost word line in the second direction. One end of the first sub-select gate has a first width in the second direction. The major portion of the first sub-select gate has a second width in the second direction. The second width is greater than the first width.

### CROSS REFERENCE TO RELATED APPLICATIONS

This application claims priority of Taiwan Patent Application No. 112107811 filed on Mar. 3, 2023, the entirety of which is incorporated by reference herein.

### BACKGROUND OF THE INVENTION

### Field of the Invention

The present disclosure relates to a semiconductor process technology, and in particular to a method of manufacturing a memory device.

### Description of the Related Art

The critical dimensions of memory elements are gradually being scaled down as development of those memory elements advances, and the resistance of lithography process is gradually increasing. As the resolution of conventional lithography processes approaches its theoretical limit, vendors have turned to methods such as double-patterning to overcome the optical limit and increase the integration of memory elements. However, due to the difference in the precision required for the lithography process of the word lines and the select gate, and considerations for the subsequent process, the select gate will be defined by multiple patterning steps using current patterning methods, and this may affect the word lines of the memory devices and cause electrical problems. Therefore, in order to pursue lower costs and make sure the product continues to perform well, the industry still needs to improve the method of manufacturing memory devices to achieve the goal of maintaining the yield of memory devices.

### BRIEF SUMMARY OF THE INVENTION

An embodiment of the present disclosure provides a method of manufacturing a memory device. The method of manufacturing the memory device includes providing a substrate and sequentially forming a stack layer and a hard mask layer on the substrate. The method further includes forming a plurality of word line patterns and a first select gate pattern on the hard mask layer, wherein the first select gate pattern has an opening at one end in the first direction, so that the first select gate pattern is U-shaped at the end in the first direction. The method further includes using the word line patterns and the first select gate pattern as a mask, sequentially patterning the hard mask layer and the stack layer to form a plurality of word lines separated from each other and a first select gate with a U-shaped end on the substrate. The method further includes performing a cutting process on the first select gate along a central line of the U-shaped end to form a first sub-select gate and a second sub-select gate separated from each other. The first sub-select gate is use to control the word lines, and the second sub-select gate is use to control another plurality of word lines.

Another embodiment of the present disclosure provides a memory device. The memory device includes a substrate. The memory device further includes a plurality of word lines disposed on the substrate. The word lines extend in the first direction and are arranged in the second direction, and the first direction intersects the second direction. The memory device further includes a first sub-select gate extending in the first direction and disposed adjacent to and separated from an outermost word line in the second direction. An end of the first sub-select gate has a first width in the second direction, a major portion of the first sub-select gate has a second width in the second direction, and the second width is greater than the first width.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1, 3, 6, and 7 illustrate top views of intermediate stages of manufacturing the memory device according to the embodiment of the present disclosure; and

FIGS. 2A, 2B, 4A, 4B, 5A, 5B, 8A, and 8B illustrate cross-sectional views of intermediate stages of manufacturing the memory device according to the embodiment of the present disclosure.

### DETAILED DESCRIPTION OF THE INVENTION

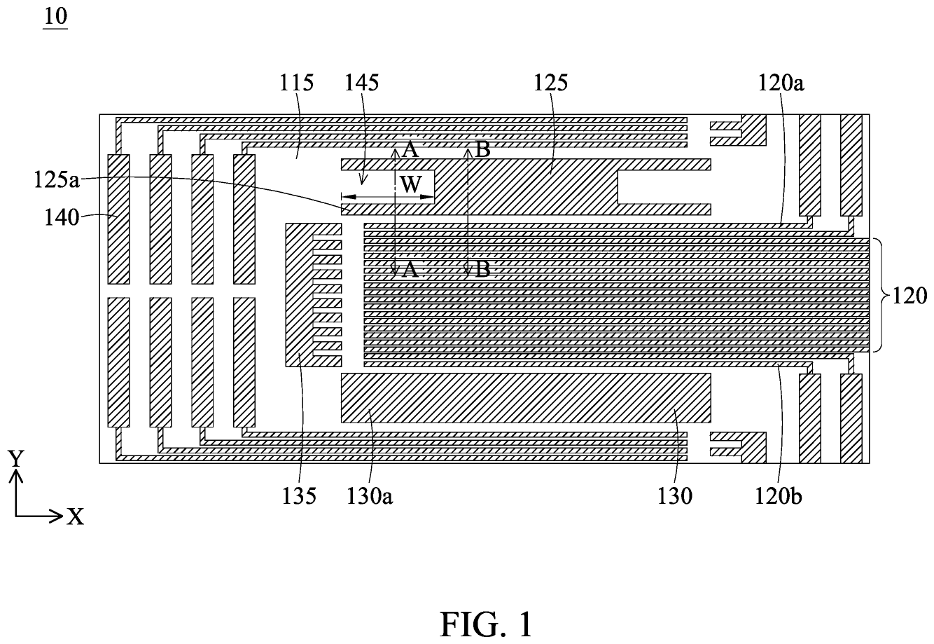

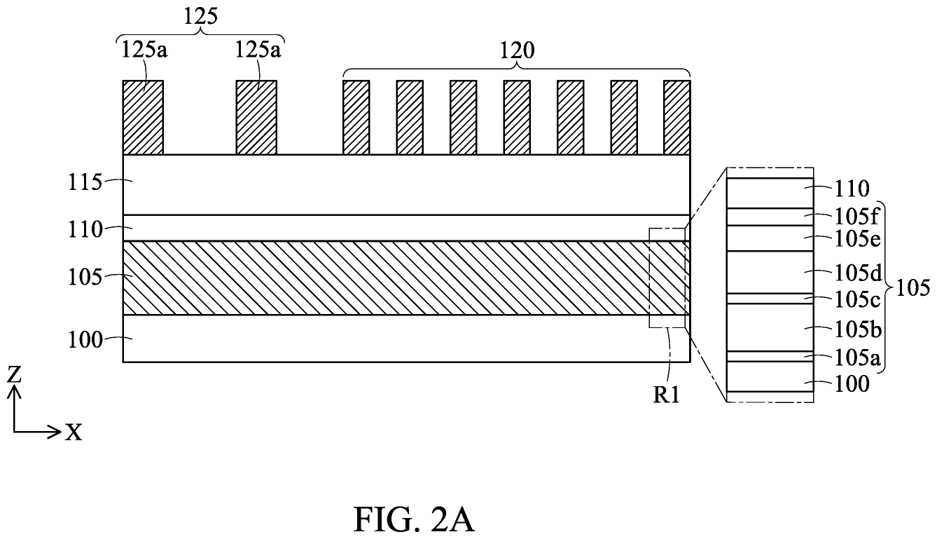

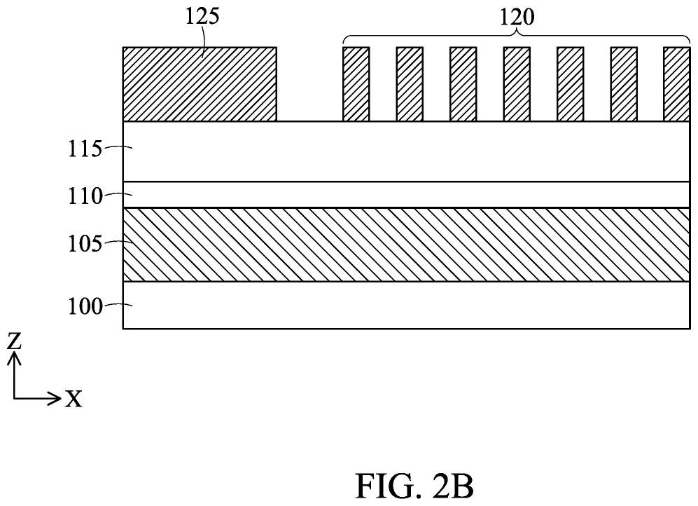

Referring to the top view of FIG. 1, and in conjunction with the cross-sectional view of FIG. 2A and FIG. 2B, the steps for forming the word line pattern 120 and the first select gate pattern 125 and the second select gate pattern 130 are illustrated. FIG. 2A and FIG. 2B illustrate the cross-sectional views corresponding to the cross-sectional line A-A and the cross-sectional line B-B in FIG. 1, respectively. A substrate 100 is provided, and a stack layer 105, a sacrificial layer 110, and a hard mask layer 115 are sequentially formed on the substrate 100. First, a stack layer 105 is formed on the substrate 100. In some embodiments, the stack layer 105 may sequentially include, in the third direction (e.g., in the Z-direction of the coordinate axis) from bottom to top, for example, a tunnel dielectric layer 105a, a floating gate layer 105b, an inter-gate dielectric layer 105c, a control gate layer 105d, a metal layer 105e, and the top capping layer 105f. For the sake of simplicity, each of the layers mentioned above only partially shown in the region R1 in FIG. 2A, and only the stack layer 105 is shown schematically in FIG. 2B. In some embodiments, the material of the tunnel dielectric layer 105a may be silicon oxide. In some embodiments, the material of the floating gate layer 105b may be a conductive material, such as doped polysilicon, undoped polysilicon, or a combination thereof. In some embodiments, the inter-gate dielectric layer 105c may be a composite layer constructed by, for example, oxide/nitride/oxide (ONO). In some embodiments, the material of the control gate layer 105d may be a conductive material, such as doped polysilicon, undoped polysilicon, or a combination thereof. In some embodiments, the material of the metal layer 105e may be such as W, TiN, or a combination thereof. In some embodiments, the material of the top capping layer 105f may be a dielectric material, such as silicon nitride, silicon oxynitride, or a combination thereof.

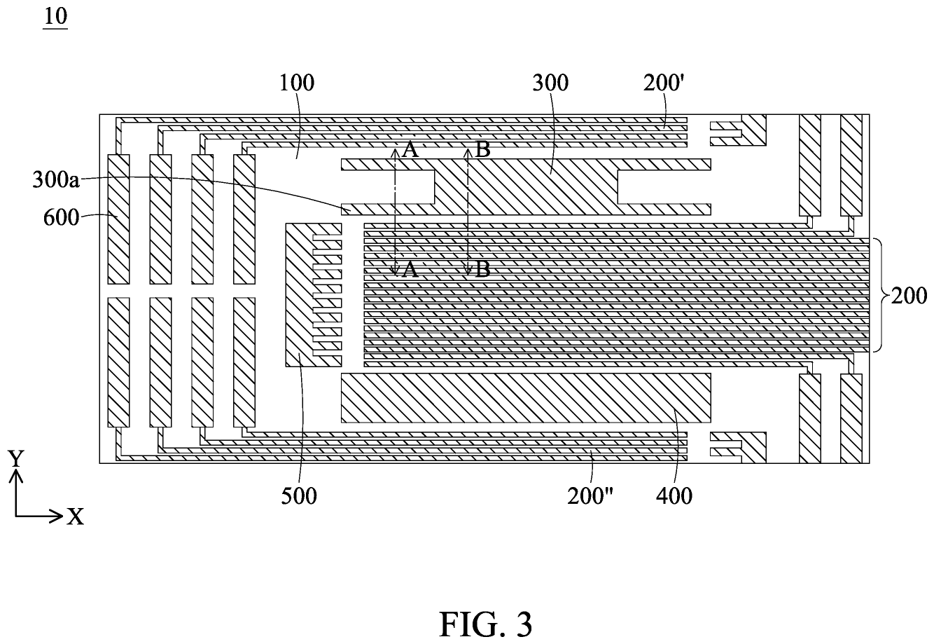

The portion of the stack layer 105 corresponding to the formation of the word line pattern 120 is subsequently formed as the word lines 200 (as shown in FIG. 3). The portion of the stack layer 105 corresponding to the formation of the first select gate pattern 125 is subsequently formed as the first select gate 300 (as shown in FIG. 3). The portion of the stack layer 105 corresponding to the formation of the second select gate pattern 130 is subsequently formed as the second select gate 400 (as shown in FIG. 3), as described later in detail.

The sacrificial layer 110 and the hard mask layer 115 are sequentially formed on the stack layer 105. The sacrificial layer 110 protects the stack layer 105 from being etched during the subsequent steps in the process of patterning the hard mask layer 115. The hard mask layer 115 may be used as a patterned mask for the stack layer 105 in subsequent steps in the process, to form, for example, the word lines 200, the first select gate 300, and the second select gate 400. In some embodiments, the material of the sacrificial layer 110 includes silicon oxide. In some embodiments, the hard mask layer 115 may be a single-layer or multi-layer structure. In some embodiments, the material of the hard mask layer 115 includes polysilicon.

The word line pattern 120, the first select gate pattern 125, the second select gate pattern 130, the dummy structure pattern 135, and the landing pad pattern 140 are continuously formed on the hard mask layer 115. In the embodiment of the present disclosure, in order to avoid the subsequent cutting process of the select gate from creating a path that may cause the chemicals used in the cleaning process to enter between the word lines 200, the end 125a of the first select gate pattern 125 in the first direction (e.g., in the X-direction of the coordinate axis) is designed to have an opening 145. That is, the end 125a of the first select gate pattern 125 in the first direction is U-shaped. This allows the subsequent cutting process to be performed with a smaller patterned opening.

The word line pattern 120 and the first select gate pattern 125 extend along the first direction (e.g., the X-direction of the coordinate axis). The first select gate pattern 125 is adjacent to and separated from the outermost word line pattern 120a in the second direction (e.g., the Y-direction of the coordinate axis). The first direction intersects the second direction. The second select gate pattern 130 is formed on the opposite side of the word line pattern 120 in the second direction from the first select gate pattern 125, in other words, the second select gate pattern 130 is adjacent to and separated from the outermost word line pattern 120b in the second direction. In some embodiments, the end 130a of the second select gate pattern 130 in the first direction is solid. In other embodiments, the second select gate pattern 130 is similar to the first select gate pattern 125, which also has a U-shaped end. In some embodiments, the width W of the opening 145 in the first direction may range from about 100 nm to about 150 nm.

The process for forming the word line pattern 120 and the dummy structure pattern 135 mentioned above may include a self-aligned multiple patterning process, such as a self-aligned double patterning (SADP) process or a self-aligned quadruple patterning (SAQP) process.

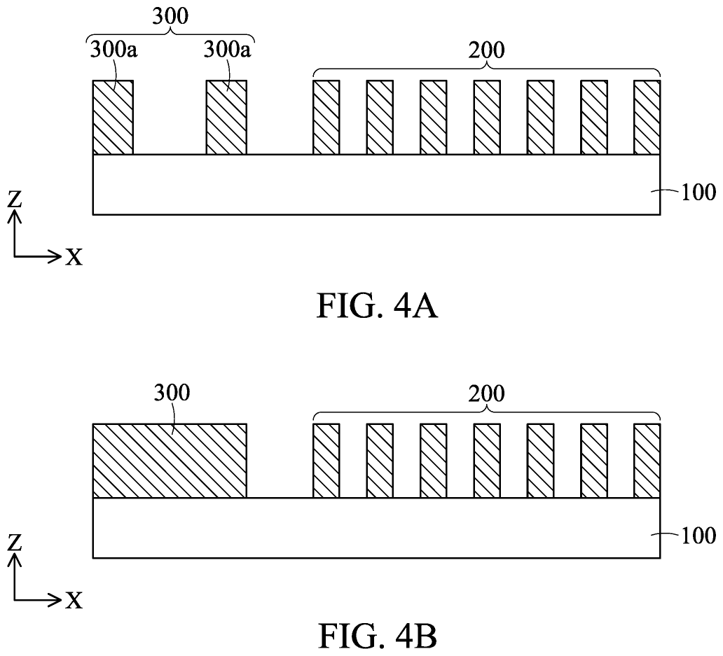

Referring to the top view of FIG. 3, and in conjunction with the cross-sectional views of FIG. 4A and FIG. 4B, the steps for forming the word lines 200, the first select gate 300, and the second select gate 400 are illustrated. FIG. 4A and FIG. 4B illustrate the cross-sectional views corresponding to the cross-sectional line A-A and the cross-sectional line B-B in FIG. 3, respectively. The word line pattern 120, the first select gate pattern 125, the second select gate pattern 130, the dummy structure pattern 135, and the landing pad pattern 140 are used as the mask to sequentially pattern the hard mask layer 115, the sacrificial layer 110, and the stack layer 105 to form the word lines 200, the first select gate 300, the second select gate 400, the dummy structure 500, and the landing pads 600 on the substrate 100, respectively. The dummy structure 500 reduces the etching load on the word lines 200. In some embodiments, since the dummy structure pattern 135 is originally an end-joined portion of the word line pattern 120, the dummy structure 500 is comb-shaped after the patterning process mentioned above has separated the word line pattern 120 from the dummy structure pattern 135. The landing pads 600 may be used as pick up points for the word lines 200. The landing pads 600 extend along the second direction (e.g., along the Y-direction of the coordinate axis) and are arranged along the first direction (e.g., along the X-direction of the coordinate axis), and are connected to the other word lines 200′ or word lines 200″, respectively. In some embodiments, the first select gate 300 has a U-shaped end 300a and the first select gate 300 and the word line 200 are separated from each other in the second direction.

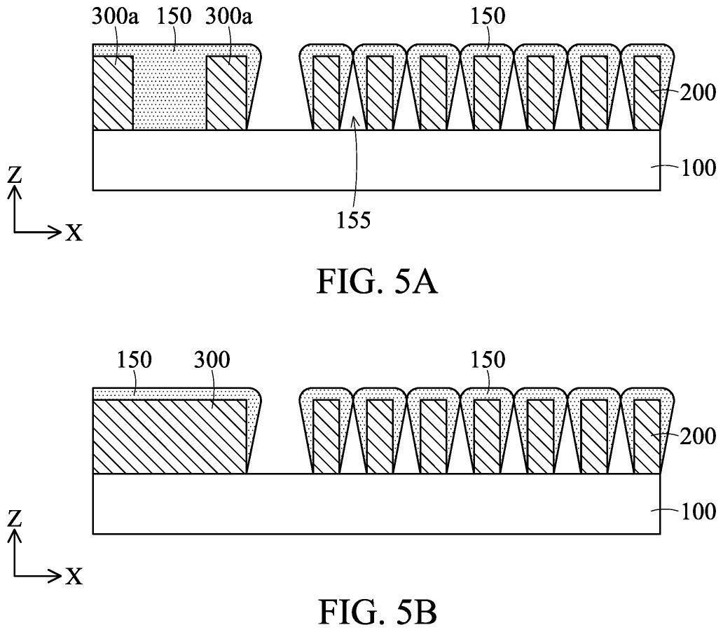

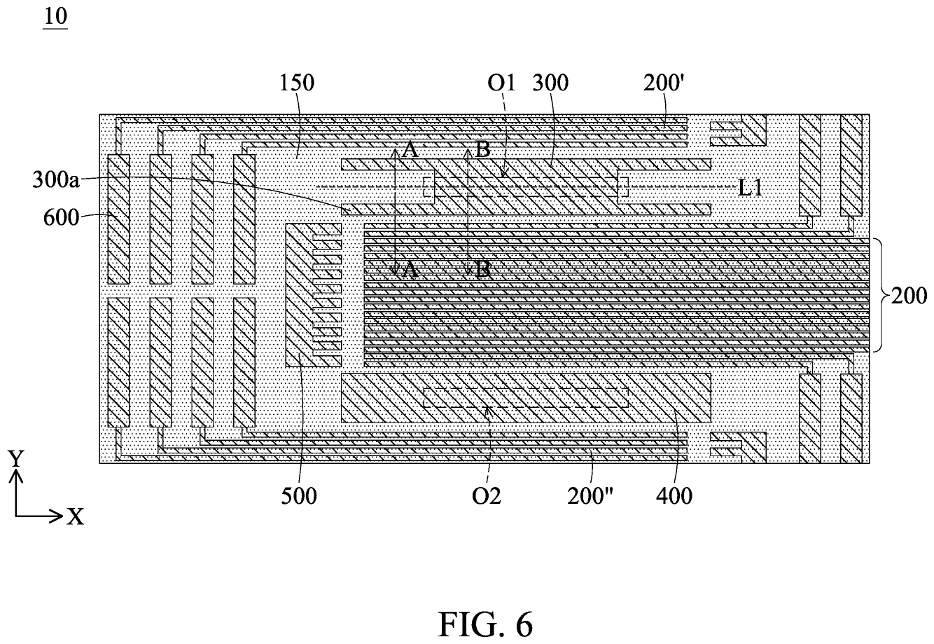

Referring to FIG. 5A and FIG. 5B, and in conjunction with the top view of FIG. 6, the steps for forming the dielectric material 150 are illustrated. FIG. 5A and FIG. 5B illustrate the cross-sectional views corresponding to the cross-sectional line A-A and the cross-sectional line B-B in FIG. 6, respectively. FIG. 6 illustrates the top view of the memory device 10 after forming the dielectric material 150. The dielectric material 150 is formed on the substrate 100 and is filled into the U-shaped end 300a of the first select gate 300, and a plurality of air gaps 155 are formed between the word lines 200. The formation of the air gaps 155 effectively suppresses parasitic capacitance between the word lines 200. In some embodiments, the air gaps 155 may be formed by a process or material with poor step coverage, thereby sealing the opening of the air gaps with the dielectric material 150 and forming the air gaps 155 before the dielectric material 150 fills the gaps between the word lines 200. It should be understood that after forming the dielectric material 150, another dielectric layer is formed to further cover the dielectric material 150 and the air gaps 155, and further fill the space between the first select gate 300 and the word lines 200, which are not shown in the figure for the sake of simplicity. In some embodiments, the dielectric material 150 may be formed by using, for example, chemical vapor deposition (CVD), and in some embodiments, the dielectric material 150 may be an oxide formed from silane or tetraethylorthosilicate (TEOS).

Still referring to FIG. 6, the cutting process is performed on the first select gate 300 along the central line L1 of the U-shaped end 300a. The cutting process is performed by first forming a patterned photoresist layer covering the entire substrate 100 (e.g., over the top surface of the dielectric material 150), with the patterned photoresist layer exposing the first opening O1 and the second opening O2 alone. Subsequently, the patterned photoresist layer is used as the mask and a suitable etching process is performed to remove the exposed portions of the first select gate 300 and the second select gate 400 from the first opening O1 and the second opening O2. It should be understood that for the sake of simplicity, only the relative positions of the first opening O1 and the second opening O2 are shown separately in FIG. 6, and the patterned photoresist layer is omitted. As described above, in order to completely cut the first select gate 300 into two sub-select gate, the cutting process requires to remove the portion inside the end of the first select gate 300. That is, the boundary of the first opening O1 in the first direction (e.g., the X-direction of the coordinate axis) needs to exceed the boundary of the portion of the first select gate 300 along the central line L1. However, by forming the U-shaped end 300a, the embodiment of the present disclosure substantially reduces the width of the first select gate 300 in the first direction, thus controlling the boundary of the first opening O1 in the first direction within the U-shaped end 300a, and avoiding damage to the dielectric material 150 outside the outer boundary of the first select gate 300 from the cutting process. In some embodiments, the etching process used for the cutting process may include a non-isotropic etching process such as a reactive ion etching (RIE) process, plasma etching, inductively coupled plasma (ICP) etching, or a combination thereof for dry etching.

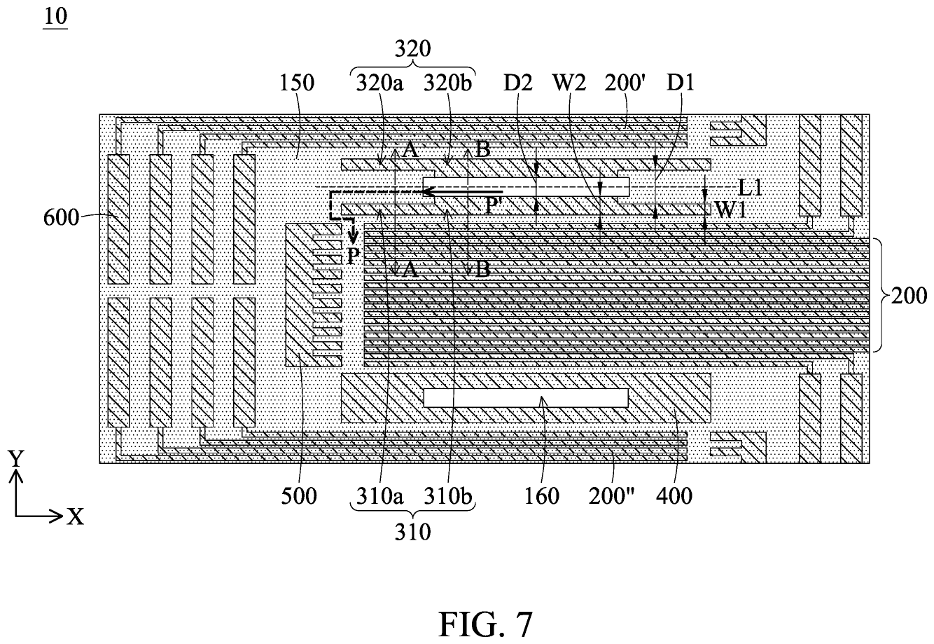

It is noted that the range of the width W of the opening 145 is described in FIG. 1 mentioned above. If the width W of the opening 145 is less than the above range, it may not be possible to effectively reduce the boundary of the patterned opening in the first direction of the cutting process (e.g., the boundary of the first opening O1 in the first direction as shown in FIG. 7), and cause the boundary of the patterned opening to remain beyond the outermost boundary of the previously defined select gate in the first direction and affect the surrounding dielectric material 150. If the width W of the opening 145 is greater than the above range, it may cause the dielectric material 150 to cover the region where the contacts will be formed or implanted later, and additional etching processes may be required to remove the dielectric material 150 covering the above region.

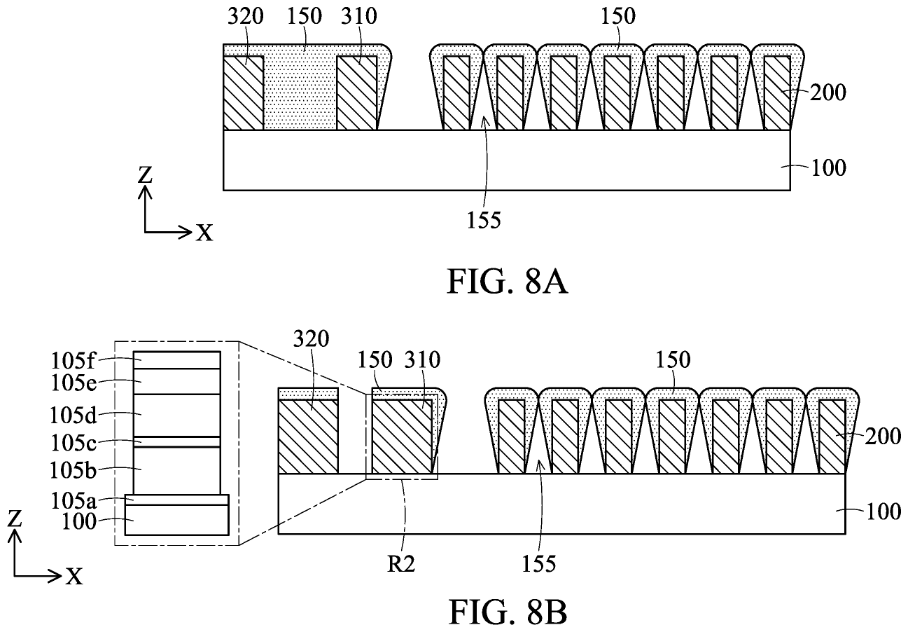

Referring to the top view of FIG. 7, and in conjunction with the cross-sectional views of FIG. 8A and FIG. 8B, the steps for forming the first sub-select gate 310 and the second sub-select gate 320 separated from each other are illustrated. FIG. 8A and FIG. 8B illustrate the cross-sectional views corresponding to the cross-sectional line A-A and the cross-sectional line B-B in FIG. 7, respectively. The cutting process removes the portions of the first select gate 300 and the second select gate 400 exposed by the first opening O1 and the second opening O2 in FIG. 6, and further removes the dielectric material 150 exposed by the first opening O1, thereby exposing the substrate 100. In some embodiments, after performing the cutting process, the first sub-select gate 310 and the second sub-select gate 320 are mirror symmetric along the central line L1 of the U-shaped end 300a, i.e., the first sub-select gate 310 is disposed in the second direction (e.g., the Y-direction of the coordinate axis) opposite to the second sub-select gate 320. In some embodiments, the first sub-select gate 310 is used to control the word lines 200, and the second sub-select gate 320 is used to control another plurality of word lines 200′. In some embodiments, the end of the second select gate 400 is solid, and the center of the second select gate 400 has an opening 160 extending along the first direction. In other words, the second select gate 400 may be a merged select gate (a conjunction of two sub-select gates with ends shorted to each other) disposed on the substrate 100, and the word lines 200 and word lines 200″ share the second select gate 400. In other embodiments, the second select gate 400 may be similar to the first select gate 300, where the U-shaped ends are first formed and then the cutting process is performed to form two sub-select gates separated from each other.

In some embodiments, the end 310a of the first sub-select gate 310 has a first width W1 in the second direction, the major portion 310b of the first sub-select gate 310 has a second width W2 in the second direction, and the second width W2 is greater than the first width W1. In some embodiments, the first width W1 may range from about 60 nm to about 100 nm. In some embodiments, the second width W2 may range from about 110 nm to about 150 nm. In some embodiments, the spacing D1 between the end 310a of the first sub-select gate 310 and the end 320a of the second sub-select gate 320 is greater than the spacing D2 between the major portion 310b of the first sub-select gate 310 and the major portion 320b of the second sub-select gate 320. In some embodiments, the spacing D1 may range from about 340 nm to about 420 nm. In some embodiments, the spacing D2 may range from about 240 nm to about 320 nm. If the spacing D1 is less than the above range, during the formation of the dielectric material 150 in FIG. 5A, the air gaps may be adversely formed at the U-shaped end 300a of the first selective gate 300 instead of completely filling the U-shaped end 300a, which may create a flow path for the chemicals used in the subsequent cleaning process.

After performing the cutting process, a cleaning process may be performed subsequently to remove the process residue remaining on the substrate. Although the cutting process removes a portion of the dielectric material 150 in the U-shaped end 300a, the remaining portion of the dielectric material 150 in the U-shaped end 300a may still be used to block the chemicals used in the cleaning process and protect the air gaps 155 from chemical etching. The dashed line path P represents the possible flow path of the chemicals. Generally, the conventional select gate process removes the dielectric material 150 outside the outer boundary of the first select gate 300, creating a path allows the chemicals to flow between the word lines 200. In the embodiment of the present disclosure, the flow path of the chemicals may be limited by the dielectric material 150 filled into the U-shaped end 300a of the first select gate 300 as shown in the solid line path P′, i.e. the cutting process may not create a path beyond the outermost boundary of the first select gate 300. The chemicals used in the cleaning process may still be blocked by the dielectric material 150, effectively avoid the chemical damage to the word lines 200. If the chemicals flow into the word lines 200 through the path P, it may remain in the air gaps 155 of the word lines 200. The cleaning process usually uses high viscosity chemicals (e.g., sulfuric acid (H₂SO₄)), so the chemicals remaining in the air gaps 155 may spread the entire air gaps 155 due to capillarity phenomenon, and its surface tension may cause the word lines 200 to bend. In some embodiment, other chemicals such as DHF, SC1 may cause unnecessary etching on the word lines 200.

FIG. 8A illustrates the dielectric material 150 filling the U-shaped end 300a (e.g., filling the space between the first sub-select gate 310 and the second sub-select gate 320) remains unetched after performing the cutting process. Region R2 of FIG. 8B illustrates a cross-sectional view of the first sub-select gate 310. The first sub-select gate 310 and the second sub-select gate 320 each have a floating gate 105b and a control gate 105d above the floating gate 105b. After performing the cutting process, the memory device 10 may continue with other semiconductor processes to form various components and elements of the memory device, for example, the spacers and the contact structures may be formed subsequently between the first sub-select gate 310 and the second sub-select gate 320.

In summary, the embodiment of the present disclosure defines and forms a sub-select gate in two processing steps. It does this to control the switching function of the specific word line. That is, in the initial step of defining the select gate, the end of the select gate is formed into a U-shape, so that the subsequent cutting process of the select gate may not damage the dielectric structure around the select gate. The path where the chemicals in the subsequent cleaning process may flow between the word line is prevented, thus maintaining the yields of the memory device.

The foregoing outlines features of several embodiments so that those skilled in the art may better understand the aspects of the present disclosure. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a memory device, comprising:
providing a substrate;
sequentially forming a stack layer and a hard mask layer on the substrate;
forming a plurality of word line patterns and a first select gate pattern on the hard mask layer, wherein the first select gate pattern has an opening at an end in a first direction, so that the first select gate pattern is U-shaped at the end in the first direction;
using the word line patterns and the first select gate pattern as a mask, sequentially patterning the hard mask layer and the stack layer to form a plurality of word lines separated from each other and a first select gate with a U-shaped end on the substrate; and
performing a cutting process on the first select gate along a central line of the U-shaped end to form a first sub-select gate and a second sub-select gate separated from each other, wherein the first sub-select gate is use to control the word lines, and the second sub-select gate is use to control another plurality of word lines.

2. The method as claimed in claim 1, wherein the first sub-select gate and the second sub-select gate are mirror symmetrical along the central line of the U-shaped end.

3. The method as claimed in claim 1, wherein the word line patterns and the first select gate pattern extend along the first direction, the first select gate pattern is adjacent to and separated from an outermost word line pattern in a second direction, and the first direction intersects the second direction.

4. The method as claimed in claim 3, wherein after performing the cutting process, a spacing between one end of the first sub-select gate and one end of the second sub-select gate is greater than a spacing between a major portion of the first sub-select gate and a major portion of the second sub-select gate.

5. The method as claimed in claim 3, further comprising:
forming a second select gate pattern on another side of the word line patterns in the second direction relative to the first select gate pattern, wherein one end of the second select gate pattern in the first direction is solid.

6. The method as claimed in claim 1, wherein after forming the word lines and the first select gate, a dielectric material is formed on the substrate and filled into the U-shaped end of the first select gate, and a plurality of air gaps are formed between the word lines.

7. The method as claimed in claim 6, wherein the cutting process removes a portion of the dielectric material, and wherein after performing the cutting process, further comprising:
performing a cleaning process, wherein the dielectric material in the U-shaped end protects the air gaps from chemical etching of the cleaning process.

8. The method as claimed in claim 1, wherein the first sub-select gate has a floating gate and a control gate above the floating gate.

9. The method as claimed in claim 1, wherein before forming the hard mask layer on the stack layer, further comprising:
forming a sacrificial layer on the stack layer, wherein the sacrificial layer protects the stack layer from being etched during the patterning of the hard mask layer.

10. The method as claimed in claim 9, wherein the hard mask layer comprises polysilicon, and the sacrificial layer comprises silicon oxide.

11. The method as claimed in claim 1, wherein a width of the opening in the first direction is about 100 nm to about 150 nm.

12. The method as claimed in claim 1, further comprising:
during the formation of the word line patterns, forming a dummy structure pattern on the hard mask layer, wherein the dummy structure pattern is adjacent to and separated from one end of the word line patterns in the first direction; and
during the sequential patterning of the hard mask layer and the stack layer, using the dummy structure pattern as a mask to form a dummy structure on the substrate.

13. A memory device, comprising:
a substrate;
a plurality of word lines disposed on the substrate, wherein the word lines extend in a first direction and are arranged in a second direction, and wherein the first direction intersects the second direction; and
a first sub-select gate extending in the first direction and disposed adjacent to and separated from an outermost word line in the second direction, wherein one end of the first sub-select gate has a first width in the second direction, a major portion of the first sub-select gate has a second width in the second direction, and the second width is greater than the first width.

14. The memory device as claimed in claim 13, wherein the first sub-select gate comprises a floating gate and a control gate above the floating gate.

15. The memory device as claimed in claim 13, further comprising:
a dummy structure adjacent to and separated from one end of the word lines in the first direction, and the dummy structure is comb-shaped.

16. The memory device as claimed in claim 13, further comprising:
a plurality of landing pads extending along the second direction and respectively connecting to another plurality of word lines.

17. The memory device as claimed in claim 13, wherein the first sub-select gate is disposed opposite to a second sub-select gate in the second direction, and the first sub-select gate and the second sub-select gate are mirror symmetrical along the first direction.

18. The memory device as claimed in claim 17, wherein the second sub-select gate is used to control another plurality of word lines.

19. The memory device as claimed in claim 13, further comprising:
a merged select gate disposed on the substrate and disposed on another side of the word lines in the second direction relative to the first sub-select gate, wherein a center of the merged select gate has an opening extending along the first direction.

20. The memory device as claimed in claim 19, wherein the word lines share the merged select gate with another plurality of word lines.
